(19) United States
(12) Patent Application Publication
(10) Pub. No.: US 2026/0297796 A1
(43) Pub. Date: Oct. 1, 2026

(54) Water-Cooling Jacket and Single Crystal Furnace

(71) Applicant: XI’AN ESWIN MATERIAL TECHNOLOGY CO., LTD., Xi'an (CN)

(72) Inventors: Wenwu YANG, Xi'an (CN); Wanliang LIANG, Xi'an (CN)

(21) Appl. No.: 19/479,596

(22) PCT Filed: Nov. 17, 2023
(86) PCT No.: PCT/CN2023/132256

§ 371 Date: Oct. 28, 2025

(30) Foreign Application Priority Data
Apr. 28, 2023 (CN) 202310476521.3

(51) Int. Cl. C30B 15/14; C30B 15/20; C30B 29/06

(52) U.S. Cl. CPC C30B 15/14; C30B 15/206; C30B 29/06

(57) ABSTRACT

A water-cooling jacket for a single crystal furnace is provided. The water-cooling jacket is of a cylinder-like structure, and a plurality of through-holes is formed in a side wall of the water-cooling jacket in a circumferential direction of the water-cooling jacket to provide a gas channel through which an inert gas passes to prevent a gas volatilized from a silicon melt in the single crystal furnace from moving upward. The single crystal furnace is further provided.

### CROSS-REFERENCE TO RELATED APPLICATION

This application is a U.S. national phase application of a PCT application No. PCT/CN 2023/132256 filed on Nov. 17, 2023, which claims a priority of the Chinese patent application No. 202310476521.3 filed on Apr. 28, 2023, which is incorporated herein by reference in its entirety.

### TECHNICAL FIELD

The present disclosure relates to the field of semiconductor wafer manufacturing, in particular to a water-cooling jacket and a single crystal furnace.

### BACKGROUND

Single crystal silicon serves as the substrate material of a majority of semiconductor elements, and it is fabricated using a Czochralski (Cz) method in most cases. In this method, a solid-state polycrystalline silicon material is placed into a crucible, and the crucible is heated to melt the polycrystalline silicon material. During the formation of a single crystal silicon ingot through lifting, a seed crystal is in contact with the molten silicon so that the molten silicon is cooled to form a solid-liquid interface and to crystallize around the seed crystal, and then the seed crystal is gradually lifted for the growth. After necking, the lifting speed and/or the temperature of the silicon melt are reduced to enlarge a growth diameter of the crystal to a target diameter. After shouldering, both the lifting speed and the temperature of the melt are regulated to transition into a stage of constant diameter growth. Finally, the lifting speed and the temperature of the melt are increased to gradually reduce a diameter of a growth surface of the crystal to form a tail cone, until the crystal detaches a surface of the melt, indicating that the growth of the single crystal silicon ingot has been completed.

During the lifting, a heater that affects the heat dissipation of the single crystal silicon ingot is crucial, because the heater zone directly affects a temperature gradient of the single crystal silicon ingot, and the temperature gradient of the single crystal silicon ingot is the most critical determining factor for the quality of the single crystal silicon ingot.

During the lifting, it is essential to heat the crucible in order to melt the polycrystalline silicon material. An inner surface of a quartz crucible reacts with the silicon melt at a high temperature to generate silicon monoxide, and silicon monoxide then ascends to react with a graphite member positioned above the crucible leading to the generation of carbon monoxide. Carbon monoxide is reintroduced in the silicon melt due to a sweeping effect, and then enters the single crystal silicon ingot to form pin holes. In addition, the single crystal silicon ingot may contain an excessive carbon constituent.

### SUMMARY

In order to solve the above-mentioned technical problems, the present application provides a water-cooling jacket and a single crystal furnace, so as to prevent the quality of a single crystal silicon ingot from being adversely affected in a case that silicon monoxide generated through the reaction of the quartz crucible with the silicon melt.

In order to achieve the above-mentioned object, the present disclosure provides the following technical solutions. The present disclosure provides in some embodiments a water-cooling jacket applied to a single crystal furnace. The water-cooling jacket is of a cylinder-like structure, and a plurality of through-holes is formed in a side wall of the water-cooling jacket in a circumferential direction of the water-cooling jacket to provide a gas channel through which an inert gas passes to prevent a gas volatilized from a silicon melt in the single crystal furnace from moving upward.

Optionally, the through-holes are arranged in at least two circles at intervals in the side wall of the water-cooling jacket in an axial direction of the water-cooling jacket.

Optionally, an adjustment structure is arranged inside the through-hole for adjusting an opening degree of the gas channel and/or adjusting an extension direction of the gas channel.

Optionally, the adjustment structure includes a semispherical shielding member rotatably arranged at the through-hole, the semispherical shielding member is in transmission connection with a driving member via a transmission shaft, the transmission shaft is movably arranged between a side wall of the through-hole and a side wall of the semispherical shielding member, and the transmission shaft moves along an axial direction of the transmission shaft under the effect of the driving member to drive the semispherical shielding member to rotate.

Optionally, an arc-like groove is formed in a peripheral surface of the semispherical shielding member to accommodate the transmission shaft, and/or an accommodation slot is formed in an interior wall of the through-hole to accommodate the transmission shaft, and the transmission shaft is coupled to the semispherical shielding member through interference fit.

Optionally, in an extension direction of the accommodation slot, a plurality of first gear slots arranges side by side in the accommodation slot, and the transmission shaft is equipped with a plurality of second gear slots in engagement with the plurality of first gear slots.

Optionally, in a radial direction of the transmission shaft, two connection rods are symmetrically arranged on two opposite inner side walls of the through-hole, and the semispherical shielding member is rotatably coupled to the two connection rods.

Optionally, the semispherical shielding member is of a hollow structure.

Optionally, in the axial direction of the water-cooling jacket, the water-cooling jacket includes a first end close to a top end of the single crystal furnace, the first end is equipped with a flange, and the flange serves to coupled the first end to a lifting structure for controlling the water-cooling jacket to move upward and downward.

Optionally, in an axial direction of the water-cooling jacket, the water-cooling jacket includes a second end away from a top end of the single crystal furnace, the second end is equipped with a gas detection structure, and the gas detection structure is configured to detect compositions of the gas moving upward to the water-cooling jacket and constituents of the compositions; and the adjustment structure adjusts the opening degree of the gas channel based on a result obtained by the gas detection structure.

The present disclosure further provides in some embodiments a single crystal furnace including the above-mentioned water-cooling jacket and a lifting structure configured to control the water-cooling jacket to move upward and downward.

The present disclosure has the following beneficial effects. The plurality of through-holes is formed in the side wall of the water-cooling jacket in the circumferential direction of the water-cooling jacket to provide the gas channel through which the inert gas passes. The water-cooling jacket is arranged above a crucible. Through the sweeping of the inert gas, it is able to prevent the gas volatilized from the silicon melt in the single crystal furnace from moving upward, prevent the gas from reacting with a graphite member above the crucible, and prevent the generation of carbon monoxide, thereby to improve the quality of the single crystal silicon ingot.

### BRIEF DESCRIPTION OF THE DRAWINGS

FIG. 1 is a schematic view showing a water-cooling jacket according to an embodiment of the present disclosure; and

FIG. 2 is a schematic view showing an adjustment structure according to an embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

During the lifting, it is essential to heat a crucible in order to melt a polycrystalline silicon material. An inner surface of a quartz crucible reacts with a silicon melt at a high temperature to generate silicon monoxide, and silicon monoxide then ascends to react with a graphite member positioned above the crucible leading to the generation of carbon monoxide. Carbon monoxide is reintroduced in the silicon melt due to a sweeping effect, and then enters a single crystal silicon ingot to form pin holes. Due to this defect, the etching process of the back-end integrated circuit is adversely affected to a great extent, leading to an increased risk of leakage current and adversely impacting product yield.

In addition, silicon monoxide ascends to react with the graphite member above the crucible to generate carbon monoxide. Carbon monoxide is reintroduced in the silicon melt due to a sweeping effect, then enters the single crystal silicon ingot, so the single crystal silicon ingot may contain an excessive carbon constituent.

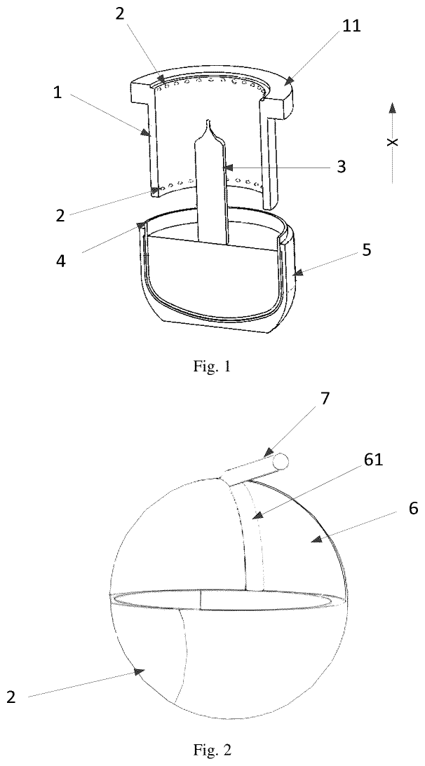

Referring to FIG. 1, in order to solve the above-mentioned problems, the present disclosure provides in some embodiments a water-cooling jacket 1 applied to a single crystal furnace. The water-cooling jacket 1 is of a cylinder-like structure, and a plurality of through-holes 2 is formed in a side wall of the water-cooling jacket 1 in a circumferential direction of the water-cooling jacket 1 to provide a gas channel through which an inert gas passes to prevent a gas volatilized from a silicon melt in the single crystal furnace from moving upward.

The through-holes 2 are formed in the side wall of the water-cooling jacket 1, allowing the inert gas enters the water-cooling jacket 1 via the through-holes 2. This configuration establishes a barrier for preventing silicon monoxide generated through the reaction of an inner surface of a quartz crucible 4 with a silicon melt to move upward. Additionally, it mitigates the generation of carbon monoxide due to the reaction of silicon monoxide with a graphite member above the quartz crucible 4. Consequently, this arrangement further protects a single crystal silicon ingot 3 from being adversely affected by carbon monoxide, prevents the generation of pin holes, and reduces a carbon constituent in the single crystal silicon ingot 3, thereby to improve the quality of the single crystal silicon ingot 3.

It should be appreciated that, in order to prevent the gas from moving upward, a flow direction of the inert gas is parallel to a radial direction of the water-cooling jacket 1. Alternatively, the inert gas flows downward inside the water-cooling jacket 1. This implies that the angle between the flow direction of the inert gas and the axial direction of the water-cooling jacket is less than 90°.

To be specific, the through-holes 2 may be arranged in various ways, as long as the gas channels for the inert gas to enter the water-cooling jacket 1 are provided. Several ways for the arrangement of the through-holes 2 will be described hereinafter.

In an illustrative embodiment of the present disclosure, the through-holes 2 are arranged in at least two circles at intervals in the side wall of the water-cooling jacket 1 in an axial direction of the water-cooling jacket 1.

Through the through-holes 2 in at least two circles, a multi-layer barrier is formed in a path in which gases, such as silicon monoxide, generated by the reaction of the inner surface of the quartz crucible 4 with the silicon melt, ascend. his configuration effectively prevents upward movement of gases generated by the reaction of the inner surface of the quartz crucible 4 with the silicon melt, specifically silicon monoxide ..

In addition, during the lifting, a heater that affects the heat dissipation of the single crystal silicon ingot 3 is crucial, because the heater zone directly affects a temperature gradient of the single crystal silicon ingot 3, and the temperature gradient of the single crystal silicon ingot 3 is the most critical determining factor for the quality of the single crystal silicon ingot 3. Through the through-holes 2 in at least two circles, it is able to facilitate the control over a change in an axial temperature gradient of the single crystal silicon ingot 3. Depending on the V/G theory, an appropriate lifting speed is provided, so as to create an environment conducive to the defect-free growth of the single crystal silicon ingot 3.

The quantity of circles of the through-holes 2, the position of the through-hole, and the distribution of the through-holes 2 in each circle are set according to the practical requirements, and will be described hereinafter in details.

In a specific embodiment of the present disclosure, in the axial direction of the water-cooling jacket 1 (direction X in FIG. 1), the water-cooling jacket 1 includes a first end close to a top end of the single crystal furnace and a second end away from the top end of the single crystal furnace (as shown in FIG. 1, in the axial direction of the water-cooling jacket, an end of the water-cooling jacket away from the quartz crucible 4 is the first end, and an end close to the quartz crucible 4 is the second end), and both the first end and the second end are equipped with the through-holes 2.

The distribution of the through-holes 2 at the first end may either correspond to or differ from the distribution of the through-holes 2 at the second end.

Illustratively, the through-holes 2 at the first end and the through-holes 2 at the second end are, but not limited to, arranged evenly in the circumferential direction of the water-cooling jacket 1.

Illustratively, the through-holes 2 at the first end are defined as a first circle of through-holes, and the first circle of through-holes includes a plurality of first through-holes arranged at intervals. The through-holes 2 at the second end are defined as a second circle of through-holes, and the second circle of through-holes includes a plurality of second through-holes arranged at intervals.

In an embodiment of the present disclosure, the orthogonal projection of the first through-hole in the first circle onto the second circle of through-holes overlaps with the orthogonal projection of the corresponding second through-hole in the second circle.

In an embodiment of the present disclosure, the orthogonal projection of the first through-hole in the first circle onto the second circle of through-holes is arranged between two adjacent second through-holes in the second circle. In this way, a flow of the gas passing through the through-holes in the first circle and a flow of the gas passing through the through-holes in the second circle effectively compensate for one another, so as to enhance the prevention of upward gas movement.

In the axial direction of the water-cooling jacket 1, in a case that two or more circles of through-holes 2 are formed in the side wall of the water-cooling jacket 1, the through-holes 2 in the two adjacent circles are arranged alternately, so that the multi-layer barrier formed by the inert gas passing through the through-holes 2 in the two or more circles compensate for each other, so as to effectively prevent the gas from moving upward.

It should be appreciated that, a diameter of the through-hole 2 is set according to the practical requirements, and a spacing between two adjacent through-holes 2 in each circle is set according to the practical requirements.

Referring to FIG. 2, in an illustrative embodiment of the present disclosure, an adjustment structure is arranged inside the through-hole 2 for adjusting an opening degree of the gas channel and/or adjusting an extension direction of the gas channel.

Through the adjustment structure, a flow direction of the gas is altered, allowing the inert gas enters the water-cooling jacket 1 at any angle. In this way, it is able to achieve a more flexible sweeping of the inert gas, prevent the gas from moving upward in a better manner, and increase the control accuracy of the change in the axial temperature gradient of the single crystal silicon ingot 3.

The adjustment structure has various structural forms, as long as the opening degree of the gas channel and/or the extension direction of the gas channel (i.e., the flow direction of the gas entering the water-cooling jacket 1) are appropriately adjusted.

In an illustrative embodiment of the present disclosure, the adjustment structure includes a semispherical shielding member 6 rotatably arranged at the through-hole 2, the semispherical shielding member 6 is in transmission connection with a driving member via a transmission shaft 7, the transmission shaft 7 is movably arranged between a side wall of the through-hole 2 and a side wall of the semispherical shielding member 6, and the transmission shaft 7 moves along an axial direction of the transmission shaft 7 under the effect of the driving member to drive the semispherical shielding member 6 to rotate.

The driving member is a driving electric motor. The transmission shaft 7 performs reciprocating motion along its axial direction under the effect of the driving member, and the semispherical shielding member 6 rotates within a plane parallel to the axial direction of the transmission shaft 7 under the effect of the transmission shaft 7.

The transmission shaft 7 is coupled to the semispherical shielding member 6 in various ways. For example, the transmission shaft 7 is coupled to the semispherical shielding member 6 through, but not limited to, interference fit. Specific coupling ways between the transmission shaft 7 and the semispherical shielding member 6 will be described hereinafter.

For example, the transmission shaft 7 is coupled to the semispherical shielding member 6 through interference fit, and there is a gap between the transmission shaft 7 and the through-hole 2, so as to facilitate the movement of the transmission shaft 7.

For example, an accommodation slot is formed in an interior wall of the through-hole 2 to accommodate the transmission shaft 7, so as to fix the transmission shaft 7 while also providing limitations and guidance for its movement.

For example, an arc-like groove 61 is formed in a peripheral surface of the semispherical shielding member 6 to accommodate the transmission shaft 7, and a radius corresponding to the arc-like groove 61 serves as a diameter of the semispherical shielding member 6, so as to providing limitations and guidance for the movement of accommodate the transmission shaft 7.

In a specific embodiment of the present disclosure, the arc-like groove 61 is formed in the peripheral surface of the semispherical shielding member 6 to accommodate the transmission shaft 7, the accommodation slot is formed in an interior wall of the through-hole 2 to accommodate the transmission shaft 7, and the transmission shaft 7 is coupled to the semispherical shielding member 6 through interference fit.

The transmission shaft 7 is limited through both the arc-like groove 61 and the accommodation slot, so that the semispherical shielding member 6 rotates within a predetermined plane.

For example, in an extension direction of the accommodation slot, a plurality of first gear slots arranges side by side in the accommodation slot, and the transmission shaft 7 is provided with a plurality of second gear slots in engagement with the plurality of first gear slots.

Through the first gear slots and the second gear slots, it is able to increase the connection stability between the transmission shaft 7 and the semispherical shielding member 6. This improvement facilitates greater accuracy in adjusting the opening degree of the gas channel, and prevents asynchronous movement between the transmission shaft 7 and the semispherical shielding member 6.

For example, in the radial direction of the transmission shaft 7, two connection rods are symmetrically arranged on two opposite inner side walls of the through-hole 2, and the semispherical shielding member 6 is rotatably coupled to the two connection rods.

The connection rods are fixedly arranged on the inner side wall of the through-hole 2, the semispherical shielding member 6 is equipped with corresponding connection holes into which the connection rods are inserted, and the connection holes are symmetrically arranged relative to a center of sphere where the semispherical shielding member 6 is located, so that the semispherical shielding member 6 rotates around the center of sphere.

It should be appreciated that, there is a gap between the connection hole and the connection rod, so as to facilitate the rotation of the semispherical shielding member 6.

In an illustrative embodiment of the present disclosure, the semispherical shielding member 6 is of a hollow structure.

In a case that the semispherical shielding member 6 is of a hollow structure, it is able to reduce a weight of the semispherical shielding member 6, thereby to facilitate the rotation thereof.

For example, in a case that the transmission shaft 7 is coupled to a top end of the side wall of the semispherical shielding member 6, an orthogonal projection of the semispherical shielding member 6 in an axial direction of the through-hole 2 covers a half of a radial section of the through-hole 2, and at this time, the opening degree of the gas channel reaches its maximum. After the semispherical shielding member 6 rotates by 90°, the orthogonal projection of the semispherical shielding member 6 in the axial direction of the through-hole 2 completely covers the through-hole 2, i.e., the gas channel is sealed off.

In an illustrative embodiment of the present disclosure, the first end of the water-cooling jacket 1 is equipped with a flange, and the flange serves to coupled the first end to a lifting structure for controlling the water-cooling jacket 1 to move upward and downward.

The flange is equipped to facilitate the coupling of the water-cooling jacket 1 to the lifting structure, so as to ensure the connection stability between the water-cooling jacket 1 and the lifting structure.

In the axial direction of the water-cooling jacket 1, the water-cooling jacket 1 includes a second end away from a top end of the single crystal furnace, the second end is equipped with a gas detection structure, and the gas detection structure is configured to detect compositions of the gas moving upward to the water-cooling jacket 1 and constituents of the compositions. The adjustment structure adjusts the opening degree of the gas channel based on a result obtained by the gas detection structure.

To be specific, in a case that the result obtained by the gas detection structure does not include a gas other than the inert gas, the semispherical shielding member 6 is controlled to rotate to seal off the through-hole 2, so as to prevent the inert gas from entering the water-cooling jacket 1 via the through-hole 2.

In a case that the result obtained by the gas detection structure includes a gas other than the inert gas (for example, silicon monoxide or carbon monoxide, which may be generated from the reaction between the quartz crucible and the graphite crucible), the semispherical shielding member 6 is controlled to rotate to open the through-hole 2.

In addition, the quantity of through-holes 2 to be opened and/or an opening degree of the through-hole 2 (i.e., the opening of the gas channel) are further controlled based on a constituent of the gas other than the inert gas in the result obtained by the gas detection structure.

For example, in a case that the through-holes 2 in at least two circles are formed in the side wall of the water-cooling jacket 1 in the axial direction of the water-cooling jacket 1, the quantity of circles in the at least two circles of the through-holes 2 and the quantity of through-holes in each circle are controlled based on the constituent of the gas other than the inert gas, as determined by the gas detection structure. This approach aims to reduce costs.

For example, the gas detection structure includes an infrared photosensitive element. Various gases exhibit different degrees of absorption for infrared light, resulting in distinct different absorption peak values. An actual absorption peak value is compared with a standard peak card to obtain the gas compositions. In addition, a gas concentration is determined based on the magnitude of a current flowing through the infrared photosensitive element.

It should be appreciated that, the inert gas, which serves as a cooling medium, is further provided via the through-hole 2, so as regulate the variations in the axial temperature gradient of the single crystal silicon ingot 3. To be specific, the quantity of through-holes 2 to be opened and/or the opening degree of the through-hole 2 are adjusted based on the change in the axial temperature gradient of the single crystal silicon ingot 3.

In an illustrative embodiment of the present disclosure, the water-cooling jacket 1 has different inner diameters in the axial direction of the water-cooling jacket 1.

In the axial direction of the water-cooling jacket 1, the inner diameters of the water-cooling jacket 1 are different, i.e., the water-cooling jacket 1 has a variable inner diameter, so as to provide different distances between different wall portions of the inner side wall of the water-cooling jacket 1 in the axial direction of the water-cooling jacket 1 and the single crystal silicon ingot 3 lifted in the single crystal furnace and passing through the water-cooling jacket 1 in a direction parallel to the axial direction. For example, a distance between an upper portion of the inner side wall of the water-cooling jacket 1 and the single crystal silicon ingot 3 is greater than a distance between a lower portion of the inner side wall of the water-cooling jacket 1 and the single crystal silicon ingot 3. Due to different distances, different portions of the single crystal silicon ingot 3 corresponding to different wall portions have different cooling rates. It should be appreciated that, a portion of the single crystal silicon ingot 3 closer to the inner side wall of the water-cooling jacket 1 has a larger cooling rate, and a portion of the single crystal silicon ingot 3 further away from the inner side wall has a smaller cooling rate. For example, the inner side wall of the water-cooling jacket 1 includes a first portion close to the first end and a second portion away from the first end, and an inner diameter of the first portion is greater than an inner diameter of the second portion. At this time, the first portion has a low cooling rate, and the second portion has a large cooling rate. Due to different cooling rates, it is able for the temperature gradient of the single crystal silicon ingot 3 to meet the requirement.

In a specific embodiment of the present disclosure, in the axial direction of the water-cooling jacket 1, the water-cooling jacket 1 includes a first end close to the top end of the single crystal furnace and a second end away from the top end of the single crystal furnace, and the inner diameter of the water-cooling jacket 1 gradually decreases from the first end to the second end.

In a case that the inner diameter of the water-cooling jacket 1 gradually decreases from the first end to the second end, it is able to provide an even temperature along the axial direction of the single crystal silicon ingot 3, thereby to improve the quality of the single crystal silicon ingot 3.

In an illustrative embodiment of the present disclosure, the water-cooling jacket 1 includes a housing and a cooling water pipeline that is coiled around a side wall of the housing.

In an illustrative embodiment of the present disclosure, an inlet and an outlet of the cooling water pipeline are arranged at an end of the housing close to the top end of the single crystal furnace, so as to facilitate the injection and discharging of cooling water.

In an illustrative embodiment of the present disclosure, the cooling water pipeline includes a first straight portion extending in the axial direction of the water-cooling jacket 1 and equipped with the inlet, a second straight portion extending in the axial direction of the water-cooling jacket 1 and equipped with the outlet, and a spiral portion surrounding the housing and arranged between the inlet and the outlet. This configuration ensures comprehensive coverage of the entire housing by the cooling water pipeline.

It should be appreciated that, the first straight portion is coupled to a proximal end of the spiral portion. The proximal end of the spiral portion is close to the first end of the water-cooling jacket 1, while a distal end of the spiral portion is close to the second end of the water-cooling jacket 1. Furthermore, the second straight portion extends from the second end to the first end. In this way, the cooling water entering the spiral portion flows from the first end to the second end along the spiral portion.

For example, a diameter of the spiral portion of the cooling water pipeline gradually decreases from the first end to the second end. The bottom portion of the single crystal silicon ingot 3, which is located near the base of the single crystal furnace, corresponds to a thinner portion of the cooling water pipeline. The cooling water flows rapidly in the thinner portion of the cooling water pipeline, resulting in enhanced heat is dissipated from the bottom portion of the single crystal silicon ingot 3. Consequently, this lower section experiences a significantly higher cooling rate. In this way, it is able to provide the single crystal silicon ingot 3 with an even temperature along the axial direction, thereby to obtain a reduced axial temperature gradient.

For example, the water-cooling jacket 1 includes an inner cylinder and an outer cylinder enveloping the inner cylinder, and the cooling water pipeline is arranged between the outer cylinder and the inner cylinder.

The outer cylinder is configured to safeguard the cooling water pipeline while also serving the purpose of providing thermal insulation.

Referring to FIG. 1, the present disclosure further provides in some embodiments a single crystal furnace, which includes the above-mentioned water-cooling jacket 1, and a lifting structure for controlling the water-cooling jacket 1 to move upward and downward.

To be specific, the single crystal furnace includes: a furnace body which defines a chamber; a crucible arranged inside the chamber, and including a quartz crucible 4 for receiving a silicon melt for forming the single crystal silicon ingot 3 through lifting and a graphite crucible 5 enveloping the quartz crucible 4; a reflector for guiding an inert gas to be above the silicon melt, the reflector being arranged at a periphery of the water-cooling jacket 1; and a lifting structure configured to control the water-cooling jacket 1 to move upward and downward.

It should be appreciated that, the above are merely the preferred embodiments of the present disclosure, but shall not be construed as limiting the scope of the present disclosure. Any person skilled in the art may make alterations and improvements without departing from the spirit and essence of the present disclosure, and these alterations and improvements shall also fall within the scope of the present disclosure.

1. A water-cooling jacket, applied to a single crystal furnace, wherein the water-cooling jacket includes of a cylinder-like structure, and a plurality of through-holes in a side wall of the water-cooling jacket in a circumferential direction of the water-cooling jacket to provide a gas channel through which an inert gas passes to prevent a gas volatilized from a silicon melt in the single crystal furnace from moving upward.

2. The water-cooling jacket according to claim 1, wherein the through-holes are arranged in at least two circles, at intervals in an axial direction in the side wall of the water-cooling jacket.

3. The water-cooling jacket according to claim 1, wherein an adjustment structure is arranged inside at least a first through-hole of the plurality of through-holes for adjusting an opening degree of the gas channel and/or adjusting an extension direction of the gas channel.

4. The water-cooling jacket according to claim 3, wherein the adjustment structure comprises a semispherical shielding member rotatably arranged at the first through-hole, the semispherical shielding member in transmission connection with a driving member via a transmission shaft, the transmission shaft is movably arranged between a side wall of the through-hole and a side wall of the semispherical shielding member, and the transmission shaft movables along an axial direction of the transmission shaft under an effect of the driving member to drive the semispherical shielding member to rotate.

5. The water-cooling jacket according to claim 4, wherein:
an arc-like groove is formed in a peripheral surface of the semispherical shielding member to accommodate the transmission shaft, and/or an accommodation slot is formed in an interior wall of the through-hole to accommodate the transmission shaft, and
the transmission shaft is coupled to the semispherical shielding member through interference fit.

6. The water-cooling jacket according to claim 5, wherein in an extension direction of the accommodation slot, a plurality of first gear slots is arranged side by side in the accommodation slot, and the transmission shaft is equipped with a plurality of second gear slots in engagement with the plurality of first gear slots.

7. The water-cooling jacket according to claim 4, wherein in a radial direction of the transmission shaft, two connection rods are symmetrically arranged on two opposite inner side walls of the first through-hole, and the semispherical shielding member is rotatably coupled to the two connection rods.

8. The water-cooling jacket according to claim 4, wherein the semispherical shielding member is of a hollow structure.

9. The water-cooling jacket according to claim 2, wherein in the axial direction of the water-cooling jacket, the water-cooling jacket comprises a first end close to a top end of the single crystal furnace, the first end is equipped with a flange, and the flange is configured to couple the first end to a lifting structure for controlling the water-cooling jacket to move upward and downward.

10. The water-cooling jacket according to claim 3, wherein in an axial direction of the water-cooling jacket, the water-cooling jacket comprises a second end away from a top end of the single crystal furnace, the second end includes gas detection structure, and the gas detection structure is configured to detect compositions of the gas moving upward to the water-cooling jacket and constituents of the compositions; and
the adjustment structure adjusts the opening degree of the gas channel based on a result obtained by the gas detection structure.

11. A single crystal furnace, comprising a water-cooling jacket and a lifting structure configured to control the water-cooling jacket to move upward and downward, wherein the water-cooling jacket includes a cylinder-like structure, and a plurality of through-holes formed in a side wall of the water-cooling jacket in a circumferential direction of the water-cooling jacket to provide a gas channel through which an inert gas passes to prevent a gas volatilized from a silicon melt in the single crystal furnace from moving upward.

12. The single crystal furnace according to claim 11, wherein the through-holes are arranged in at least two circles, the at least two circles disposed at intervals in an axial direction in the side wall of the water-cooling jacket.

13. The single crystal furnace according to claim 11, wherein an adjustment structure is arranged inside at least a first through-hole of the plurality of through-holes for adjusting an opening degree of the gas channel and/or adjusting an extension direction of the gas channel.

14. The single crystal furnace according to claim 13, wherein the adjustment structure comprises a semispherical shielding member rotatably arranged at the first through-hole, the semispherical shielding member is in transmission connection with a driving member via a transmission shaft, the transmission shaft is movably arranged between a side wall of the through-hole and a side wall of the semispherical shielding member, and the transmission shaft moves along an axial direction of the transmission shaft under an effect of the driving member to drive the semispherical shielding member to rotate.

15. The single crystal furnace according to claim 14, wherein:
an arc-like groove is formed in a peripheral surface of the semispherical shielding member to accommodate the transmission shaft, and/or an accommodation slot is formed in an interior wall of the through-hole to accommodate the transmission shaft, and the transmission shaft is coupled to the semispherical shielding member through interference fit.

16. The single crystal furnace according to claim 15, wherein in an extension direction of the accommodation slot, a plurality of first gear slots is arranged side by side in the accommodation slot, and the transmission shaft is equipped with a plurality of second gear slots in engagement with the plurality of first gear slots.

17. The single crystal furnace according to claim 14, wherein in a radial direction of the transmission shaft, two connection rods are symmetrically arranged on two opposite inner side walls of the first through-hole, and the semispherical shielding member is rotatably coupled to the two connection rods.

18. The single crystal furnace according to claim 14, wherein the semispherical shielding member is of a hollow structure.

19. The single crystal furnace according to claim 12, wherein in the axial direction of the water-cooling jacket, the water-cooling jacket comprises a first end close to a top end of the single crystal furnace, the first end is equipped with a flange, and the flange is configured to couple the first end to a lifting structure for controlling the water-cooling jacket to move upward and downward.

20. The single crystal furnace according to claim 13, wherein in an axial direction of the water-cooling jacket, the water-cooling jacket comprises a second end away from a top end of the single crystal furnace, the second end includes a gas detection structure, and the gas detection structure is configured to detect compositions of the gas moving upward to the water-cooling jacket and constituents of the compositions; and
the adjustment structure adjusts the opening degree of the gas channel based on a result obtained by the gas detection structure.
